(19) United States
(12) Patent Application Publication
(10) Pub. No.: US 2010/0181569 A1
(43) Pub. Date: Jul. 22, 2010

(54) DISPLAY DEVICE AND MANUFACTURING METHOD OF THE SAME

(75) Inventor: Dong-Gyu KIM, Yongin-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/477,542

(22) Filed: Jun. 3, 2009

(30) Foreign Application Priority Data
Jul. 2, 2008 (KR) 10-2008-0063972

(51) Int. Cl. H01L 33/00

(52) U.S. Cl. 257/59; 438/34; 438/151; 257/E33.053

(57) ABSTRACT

A display device for preventing misalignment of data lines and pixel electrodes, and a manufacturing method of the display device are provided. The display device includes an insulation substrate, line wiring formed on the insulation substrate, an organic insulating pattern covering the top surface and side surfaces of a portion of the line wiring, a first insulating layer formed on the organic insulating pattern and the insulation substrate, and transparent conductive patterns formed on the first insulating layer, wherein boundaries of the transparent conductive patterns are positioned on inclined surfaces of the first insulating layer in a portion thereof corresponding to the organic insulating pattern.

This application claims priority to Korean Patent Application No. 10-2008-0063972, filed on Jul. 2, 2008, and all the benefits accruing therefrom under 35 U.S.C. §119, the contents of which in its entirety are herein incorporated by reference.

### BACKGROUND OF THE INVENTION

(a) Field of the Invention

The present invention relates to a display device and a manufacturing method of the same. More particularly, the present invention relates to a display device for preventing misalignment of data lines and pixel electrodes, and a manufacturing method of the display device.

(b) Description of the Related Art

A general liquid crystal display (“LCD”) device includes a lower substrate having pixel electrodes, an upper substrate having a common electrode, and a liquid crystal layer disposed between the lower substrate and the upper substrate and having dielectric anisotropy. The pixel electrodes are disposed in a matrix pattern and are connected with a switching element such as a thin film transistor (“TFT”) to receive a data voltage. The common electrode is formed on the front surface of the upper substrate to receive a common voltage. The pixel electrode, the common electrode, and the liquid crystal layer may form a liquid crystal capacitor. The liquid crystal capacitor and the switching element connected thereto constitute basic units of a pixel.

The LCD device may apply a voltage to two electrodes so as to form an electric field in a liquid crystal layer and control the magnitude of the electric field to thereby control transmittance of light transmitting through the liquid crystal layer, to form a desired image.

In order to prevent liquid crystal degradation as the electric field is unidirectionally applied to the liquid crystal layer over a long period of time, the polarity of the data voltage with respect to the common electrode may change for each frame.

Also, various methods have been proposed to improve dynamic image characteristics of the LCD device. For example, a high-speed driving method for driving the LCD device at a speed of 120 frames per second is being developed. The high speed frame used for the high-speed driving method generally consumes a very large amount of power. Therefore, there has been an attempt to apply a column inversion driving method among inversion driving methods associated with the polarity of the data voltage and thereby reduce the power consumption.

The column inversion driving method is a driving method that applies the same polarity of data voltage to the same data line for a single frame and changes the polarity of the data voltage for each frame. In the case of the column inversion driving method, since the voltage polarity with respect to the same data line is the same for the single frame, it is possible to substantially improve the power consumption characteristic.

### BRIEF SUMMARY OF THE INVENTION

It has been determined herein, according to the present invention, that a column inversion driving method includes some disadvantages as follows. One lies in that when a positive polarity or a negative polarity of voltages is applied to each pixel electrode for the single frame for the same image, a stripe defect may occur due to different parasitic capacitance occurring according to an alignment relationship between pixel electrodes and data lines.

Exemplary embodiments of the present invention provide a display device that can prevent misalignment of data lines and pixel electrodes, and a manufacturing method of the display device.

According to exemplary embodiments of the present invention, there is provided a display device including an insulation substrate, line wiring formed on the insulation substrate, an organic insulating pattern covering a top surface and side surfaces of a portion of the line wiring, a first insulating layer formed on the organic insulating pattern and the insulation substrate, and transparent conductive patterns formed on the first insulating layer, wherein boundaries of the transparent conductive patterns are positioned on inclined surfaces of the first insulating layer in a portion of the transparent conductive patterns corresponding to the organic insulating pattern.

According to other exemplary embodiments of the present invention, there is provided a display device including a substrate, a gate line formed on the substrate, a gate insulating layer formed on the gate line and the substrate, a data line formed on the gate insulating layer, an organic insulating pattern formed on the data line and the gate insulating layer to cover a top surface and side surfaces of a portion of the data line, a passivation layer formed on the organic insulating pattern and the gate insulating layer, and transparent conductive patterns formed on the passivation layer, wherein boundaries of the transparent conductive patterns are positioned on inclined surfaces of the passivation layer in a portion of the transparent conductive patterns corresponding to the organic insulating pattern.

In this instance, the organic insulating pattern may be symmetrical based on a central line of the organic insulating pattern, and boundaries of the transparent conductive patterns may be symmetrically disposed based on the central line of the organic insulating pattern.

Also, the first insulating layer or the passivation layer may include inclined surfaces formed on the organic insulating pattern and the intermediate surface between the inclined surfaces. In this instance, the boundaries of the transparent conductive patterns may be positioned on the inclined surfaces of the first insulating layer or the passivation layer, respectively. The inclined surfaces may include linear inclined surfaces and/or curved inclined surfaces.

The display device may further include a storage capacitor line, a storage capacitor pattern overlapping the storage capacitor line to be electrically connected to one of the transparent conductive patterns, and a storage capacitor extension line extended along the data line to be electrically connected to the storage capacitor line, wherein one of the transparent conductive patterns includes an opening formed on the storage capacitor pattern.

The display device may further include a domain forming semiconductor pattern formed on the gate insulating layer, a domain forming conductive pattern formed on the domain forming semiconductor pattern, and another organic insulating pattern formed on the domain forming conductive pattern, wherein one of the transparent conductive patterns includes an opening formed on the domain forming conductive pattern, and the domain forming semiconductor pattern and the domain forming conductive pattern are obliquely extended with respect to the data line.

According to still other exemplary embodiments of the present invention, there is provided a manufacturing method of a display device, the method including forming a gate line on a substrate, forming a gate insulating layer on the gate line and the substrate, forming a data line on the gate insulating layer, forming an organic insulating pattern on the data line and the gate insulating layer, wherein forming the organic insulating pattern includes covering a top surface and side surfaces of a portion of the data line through a reflow process, forming a passivation layer on the organic insulating pattern and the gate insulating layer, and forming transparent conductive patterns on the passivation layer, wherein boundaries of the transparent conductive patterns are positioned on inclined surfaces of the passivation layer in a portion of the transparent conductive patterns corresponding to the organic insulating pattern.

According to exemplary embodiments of the present invention, a lower substrate has substantially the same parasitic capacitance between data lines and adjacent pixel electrodes. Therefore, it is possible to reduce a stripe defect occurring due to a difference in parasitic capacitance.

The present invention may be performed by various exemplary embodiments and combinations thereof, and principles of the present invention are not limited to particular exemplary embodiments.

### BRIEF DESCRIPTION OF THE DRAWINGS

The above and other features and advantages of the present invention will become more apparent by describing in detail exemplary embodiments thereof with reference to the accompanying drawings, wherein:

FIG. 1 is a top plan view of an exemplary lower substrate of an exemplary liquid crystal display (“LCD”) according to an exemplary embodiment of the present invention;

FIGS. 2 to 8 are cross-sectional views cut along line II-II′ to VIII-VIII′ of FIG. 1;

FIG. 9 is a top plan view of an exemplary lower substrate of an exemplary LCD according to another exemplary embodiment of the present invention;

FIG. 10 is a cross-sectional view cut along line X-X′ of FIG. 9;

FIG. 11 is a top plan view of a lower substrate of an exemplary LCD according to still another exemplary embodiment of the present invention;

FIG. 12 is a cross-sectional view cut along line XII-XII′ of FIG. 11;

FIG. 13 is a cross-sectional view of an exemplary LCD for forming multiple domains in the exemplary LCD of FIG. 11; and,

FIGS. 14A to 14M are cross-sectional views of the exemplary lower substrate of the exemplary LCD cut along line XIV-XIV′ of FIG. 1 for describing an exemplary display device manufacturing process.

### DETAILED DESCRIPTION OF THE INVENTION

Hereinafter, exemplary embodiments of the present invention will be described with reference to the accompanying drawings. As those skilled in the art would realize, the described embodiments may be modified in various different ways, all without departing from the spirit or scope of the present invention. In the figures, thicknesses and sizes are enlarged to clearly represent a plurality of layers and regions. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Spatially relative terms, such as “below,” “beneath,” “lower,” “above,” “upper,” and the like, may be used herein for ease of description to describe one device or element's relationship to another device(s) or element(s) as illustrated in the drawings. It will be understood that the spatially relative terms are intended to encompass different orientations of the device in use or operation in addition to the orientation depicted in the drawings.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

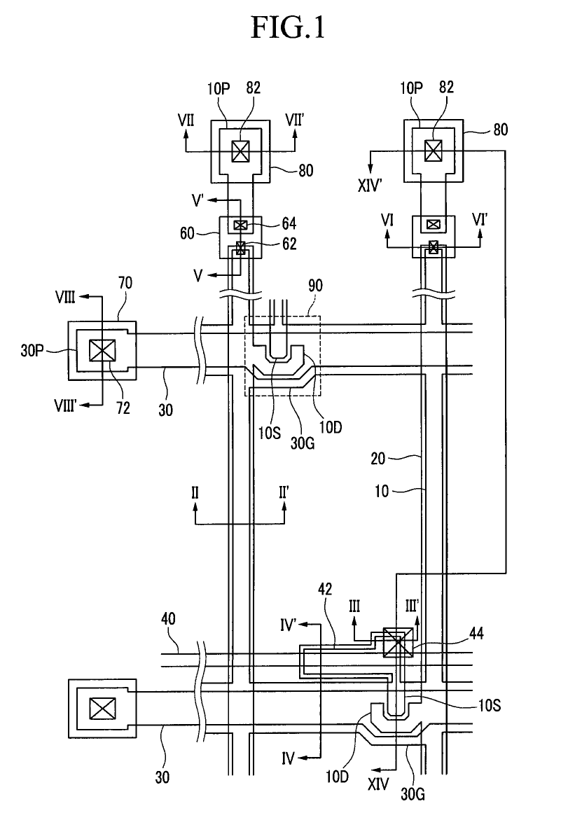

Now, a liquid crystal display (“LCD”) according to an exemplary embodiment of the present invention will be described in detail with the reference to FIG. 1 to FIG. 14M.

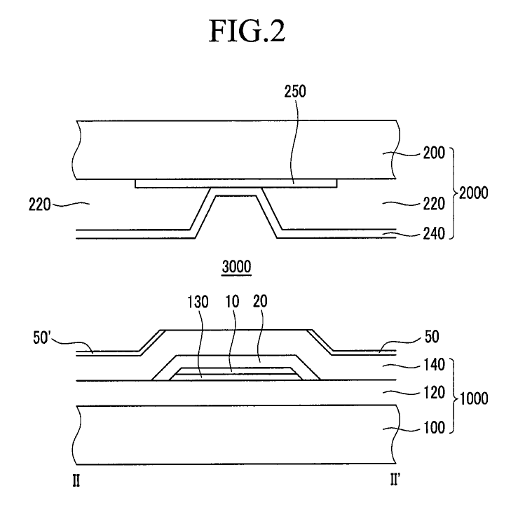

FIG. 1 is a top plan view of an exemplary lower substrate of an exemplary LCD according to an exemplary embodiment of the present invention, and FIGS. 2 to 8 are cross-sectional views cut along line II-II′ to VIII-VIII′ of FIG. 1, respectively.

As shown in FIGS. 1 to 8, a lower substrate 1000 includes a plurality of gate lines 30, a plurality of data lines 10, and a plurality of transparent conductive patterns, that is, pixel electrodes 50, that are electrically connected to the data lines 10 via switching elements 90. An upper substrate 2000 includes a black matrix 250, a plurality of color filters 220, and a common electrode 240.

A liquid crystal capacitor Clc includes two electrodes. One is a pixel electrode 50 formed on the lower substrate 1000, and the other is the common electrode 240 formed on the upper substrate 2000. A liquid crystal layer 3000 is disposed between the pixel electrode 50 and the common electrode 240. The pixel electrode 50 is connected to the switching element 90, and the common electrode 240 is formed on the upper substrate 2000. A common voltage Vcom is applied to the common electrode 240.

A storage capacitor Cst supplementing a liquid crystal capacitor Clc also includes two electrodes. One is a storage capacitor line 40 and the other is a storage capacitor pattern 42 that is electrically connected to a pixel electrode 50. A gate insulating layer 120 is disposed between the two electrodes 40 and 42. A fixed voltage such as the common voltage Vcom is applied to the storage line 40. Alternatively, the storage capacitor Cst may be formed by a pixel electrode 50 and the storage capacitor line 40, or by the pixel electrode 50 and a previous gate line 30 overlapping with the pixel electrode 50, without the storage capacitor pattern 42. The storage capacitor pattern 42 may also be integrally formed with a source electrode 10S of the switching element 90.

Referring to FIG. 1, the gate lines 30 transmit gate signals and the data lines 10 transmit data signals. The gate lines 30 are extended in the horizontal direction, a first direction, to be substantially parallel with each other, and the data lines 10 are extended in the vertical direction, a second direction, to be substantially parallel with each other. The first direction may be substantially perpendicular to the second direction.

The switching element 90 disposed in the lower substrate 1000 is a 3-terminal element such as a thin film transistor (“TFT”). A gate electrode 30G of the switching element 90 is connected to the gate line 30, a drain electrode 10D thereof is connected to the data line 10, and the source electrode 10S thereof is connected to the pixel electrode 50.

A gate pad 30P may be electrically connected to the gate line 30, and a data pad 10P may be electrically connected to the data line 10. The gate pad 30P and the data pad 10P may be formed of the same material as the gate line 30 formed on a first substrate 100. The data pad 10P is connected to the data line 10 via contact holes 64 and 62, and a bridge conductive pattern 60. Since the data pad 10P may be coupled with an external circuit by thermal compression, it may be difficult to use the data line 10 covered by on organic insulating pattern 20 as the data pad 10P.

An auxiliary gate pad 70 may be electrically connected to the gate pad 30P, and an auxiliary data pad 80 may be electrically connected to the data pad 10P. The auxiliary gate pad 70 and the auxiliary data pad 80 may be formed of the same material as the pixel electrode 50, and may be respectively connected to the gate pad 30P and the data pad 10P via contact holes 72 and 82 that passes through the gate insulating layer 120.

Referring to FIG. 2, the data line 10 is formed on the first substrate 100 that includes the gate insulating layer 120. Also, when the data line 10 is consecutively formed together with a semiconductor pattern 130 through one photolithography process, the semiconductor pattern 130 may be formed on and below the bottom surface of the data line 10 and on and above the top surface of the gate insulating layer 120, such that the semiconductor pattern 130 is disposed between the data line 10 and the gate insulating layer 120. The organic insulating pattern 20 covers the top surface and side surfaces of the data line 10 in a display region, and is formed of a photosensitive material such as a photoresist. The organic insulating pattern 20 may have a width of about 6 um to about 7 um.

In order to cover the side surfaces, the organic insulating pattern 20 symmetrically covers the data line 10, or the data line 10 and the semiconductor pattern 130. A passivation layer 140 is symmetrically formed on the organic insulating pattern 20 based on a central line of the organic insulating pattern 20. Adjacent transparent conductive patterns, that is, boundaries of pixel electrodes 50 and 50′, are formed on the passivation layer 140 to be symmetrically separated from the central line of the organic insulating pattern 20. The boundaries of the pixel electrodes 50 and 50′ are positioned on inclined surfaces of the passivation layer 140, respectively. The inclined surfaces of the passivation layer 140 overlap the portions of the organic insulating pattern 20 that cover the side surfaces of the data line 20. Particularly, the boundaries of the pixel electrodes 50 and 50′ may be formed along the inclined surfaces and boundaries of an intermediate surface positioned between the inclined surfaces. In this exemplary embodiment, the boundaries of the pixel electrodes 50 and 50′ do not overlap with the data line 10.

By symmetrically forming the passivation layer 140 and the pixel electrodes 50 and 50′ based on the central line of the organic insulating layer 20, substantially the same parasitic capacitances may be formed between the pixel electrodes 50 and 50′, and the data line 10.

When the organic insulating pattern 20 is formed of a light shielding material, the black matrix 250 formed on a second substrate 200 may be omitted. In addition, the black matrix 250 may be formed of the same material as the organic insulating pattern 20.

The color filters 220 are formed on the second substrate 200 or the black matrix 250. The common electrode 240 is formed on the color filter 220. The common electrode 240 may be directly connected to the black matrix 250.

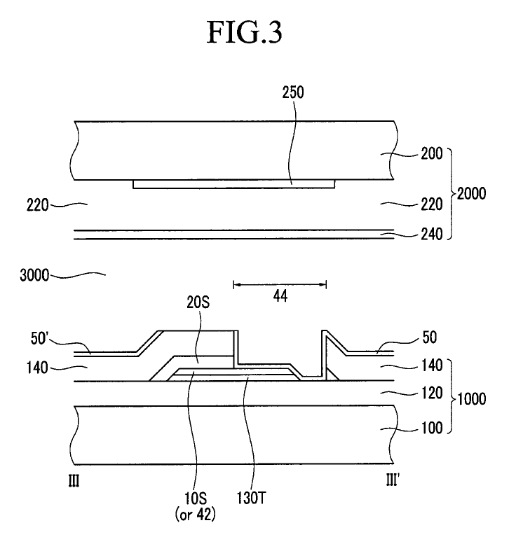

FIG. 3 shows a contact hole 44. The contact hole 44 is for connecting the pixel electrode 50 to the source electrode 10S that is electrically connected to the data line 10 when the switching element 90 is turned on.

The contact hole 44 passes through the passivation layer 140 and an organic insulating pattern 20S to thereby expose the source electrode 10S and the gate insulating layer 120, and in some cases, the first substrate 100. As shown in FIG. 1, the source electrode 10S may be integrally formed with the storage capacitor pattern 42. Alternatively, the source electrode 10S may be separated from the storage capacitor pattern 42.

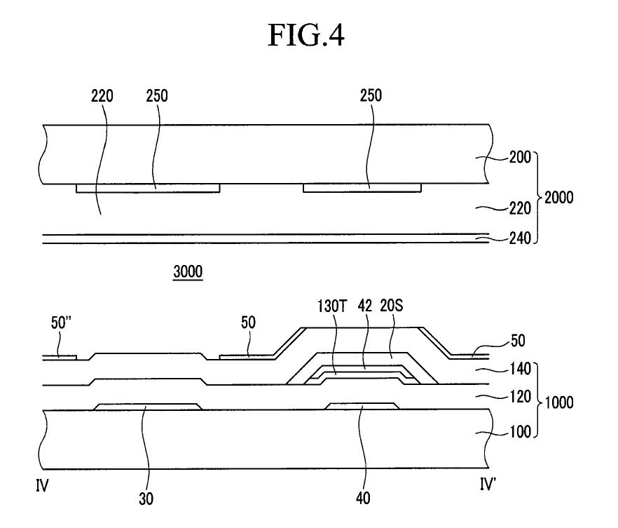

The pixel electrode 50 is connected to the source electrode 10S via an opening in the organic insulating pattern 20S and the passivation layer 140, and may include an opening formed relative to the organic insulating pattern 20S, as will be described further with respect to FIG. 4. The black matrix 250 is formed on the second substrate 200 at a portion corresponding to the contact hole 44. This is because molecules included in a liquid crystal layer 3000 formed at the contact hole 44 are not well controlled.

When the source electrode 10S and/or the storage capacitor pattern 42 and a semiconductor pattern 130T are consecutively formed through one photolithography process, the semiconductor pattern 130T may be formed below and on the bottom surface of the source electrode 10S and/or the storage capacitor pattern 42 and above and on the top surface of the gate insulating layer 120, such that the semiconductor pattern 130T is sandwiched between the gate insulating layer 120 and the source electrode 10S and/or the storage capacitor pattern 42.

Referring to FIG. 4, the opening of the pixel electrode 50 is formed relative to the storage capacitor pattern 42, such that the opening of the pixel electrode 50 overlaps the storage capacitor pattern 42. The black matrix 250 is formed on the second substrate 200 at a portion corresponding to the gate line 30 and the storage capacitor pattern 42. If the organic insulating pattern 20 is formed of a light shielding material, the black matrix 250 corresponding to the storage capacitor pattern 42 may be omitted.

A pixel electrode 50″ may be electrically insulated from the pixel electrode 50. Depending on embodiments, the pixel electrode 50″ may partially overlap an auxiliary storage capacitor or the previous gate line 30 for repair.

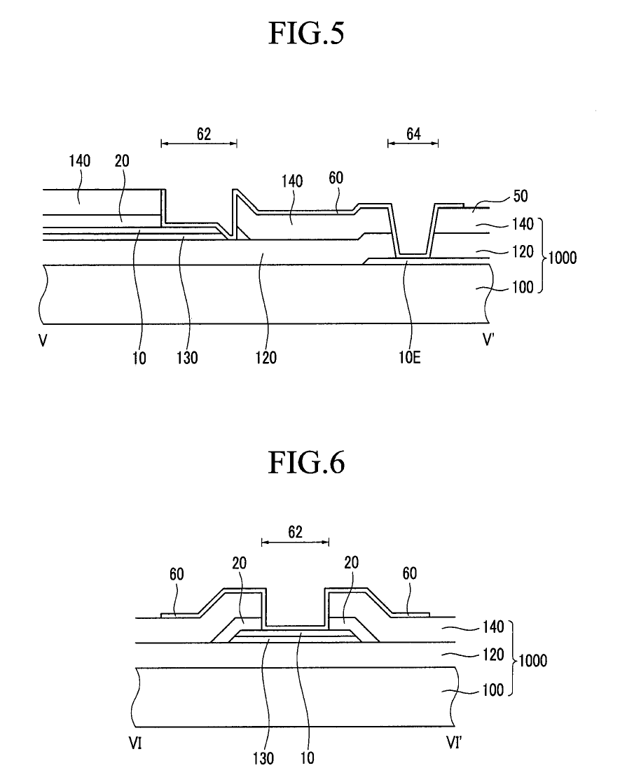

FIGS. 5 and 6 show contact holes 62 and 64. The contact holes 62 and 64 may connect the data line 10 to an extension line 10E, connected to the data pad 10P, via the bridge conductive pattern 60. The extension line 10E may be formed directly on the first substrate 100 as is the data pad 10P.

The contact hole 62 has substantially the same structure as the contact hole 44 of FIG. 3. The contact hole 64 passes through the passivation layer 140 and the gate insulating layer 120 to thereby expose the extension line 10E.

The bridge conductive pattern 60 may be formed of the same material as the pixel electrode 50. As shown in FIG. 6, the bridge conductive pattern 60 is symmetrically formed on the passivation layer 140 based on the central line of the organic insulating pattern 20.

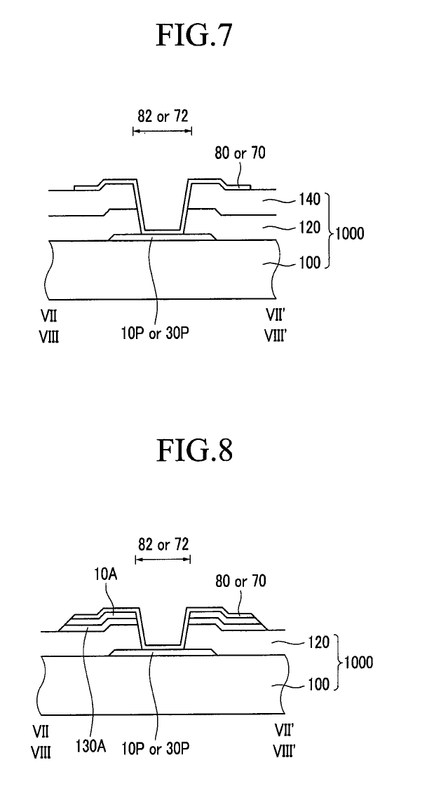

Referring to FIGS. 7 and 8, pad structures corresponding to the gate pad 30P and the data pad 10P may be replaceable.

In FIG. 7, a contact hole 82 or 72 passes through the passivation layer 140 and the gate insulating layer 120 to thereby expose the data pad 10P or gate pad 30P, which are formed on the first substrate 100. In FIG. 8, the contact hole 82 or 72 passes through the auxiliary pattern 10A and/or 130A and the gate insulating layer 120 to thereby expose the data pad 10P or gate pad 30P.

The auxiliary pad 70 or 80 is connected to the data pad 10P or gate pad 30P via the contact hole 70 or 82. The auxiliary patterns 10A and/or 130A may be formed around the contact hole 70 or 82 passing through the gate insulating layer 120.

Depending on embodiments, the gate insulating layer 120 may be removed around a pad region where the auxiliary patterns 10A and/or 130A do not exist. The passivation layer 140 may be removed from the top surface of the auxiliary patterns 10A and/or 130A, or from the entire pad region.

The auxiliary pads 70 and 80 may be formed of the same material as the pixel electrode 50. The auxiliary pattern 10A may be formed of the same material as the data line 10. Another auxiliary pattern 130A may be formed of the same material as the semiconductor pattern 130.

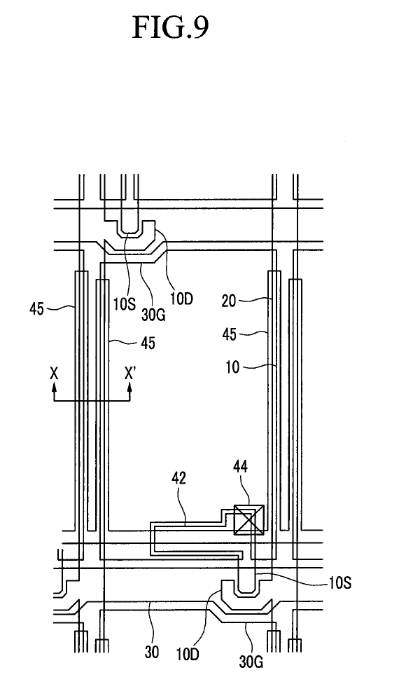

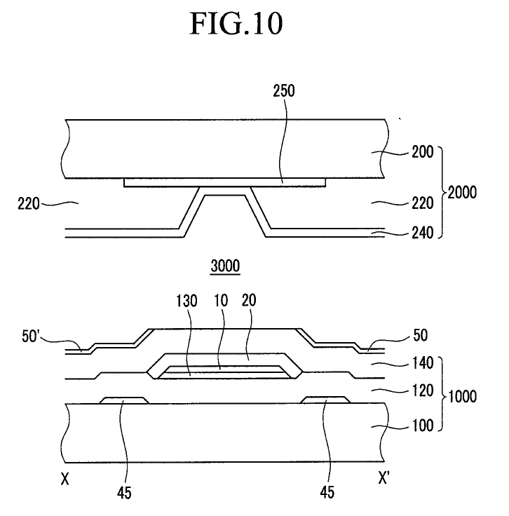

FIG. 9 is a top plan view of an exemplary lower substrate of an exemplary LCD according to another exemplary embodiment of the present invention, and FIG. 10 is a cross-sectional view cut along line X-X′ of FIG. 9.

Referring to FIGS. 9 and 10, in comparison to the above-described embodiment of FIG. 1, the present exemplary embodiment further includes a storage capacitor extension line 45 that is extended adjacent to the data line 10, such that the data line 10 overlaps an area between the two adjacent sections of the extension line 45.

Since the storage capacitor extension line 45 provides auxiliary storage capacitance, a storage capacitor pattern 42 of FIG. 9 may be formed in a smaller size than the storage capacitor pattern 42 of FIG. 1.

The storage capacitor extension line 45 may be formed of the same material as the gate line 30 on the first substrate 100. The adjacent storage capacitor extension lines 45 are symmetrically disposed based on a central line of the organic insulating pattern 20 formed on the data line 10. The storage capacitor extension line 45 includes sections that extend in the second direction, substantially perpendicular to the storage capacitor line 40.

Other constituent elements excluding the storage capacitor extension line 45 are substantially the same as the constituent elements described above with reference to FIGS. 1 to 8.

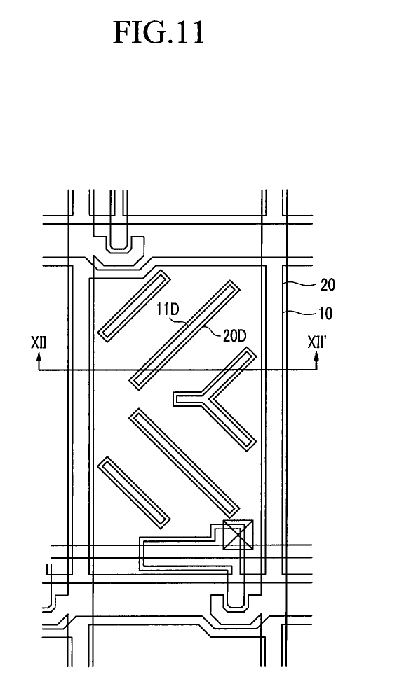

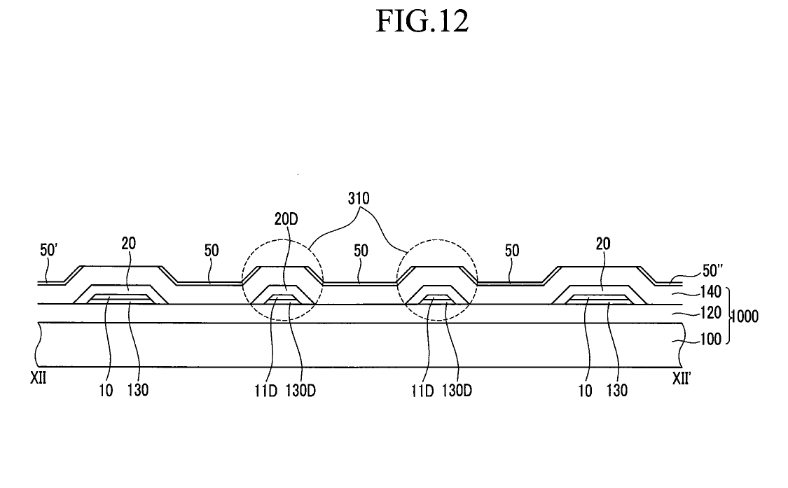

FIG. 11 is a top plan view of an exemplary lower substrate of an exemplary LCD according to still another exemplary embodiment of the present invention, and FIG. 12 is a cross-sectional view cut along line XII-XII′ of FIG. 11.

Referring to FIGS. 11 and 12, in comparison to the above-described embodiment of FIG. 1, the present exemplary embodiment further includes an organic insulating pattern 20D and a first domain forming element 310. The first domain forming element 310 includes a domain forming semiconductor pattern 130D and/or a domain forming conductive pattern 11D.

The first domain forming element 310 is obliquely extended with respect to the data line 10. In the pixel electrode 50, the first domain forming elements 310 are disposed in the shape of a chevron and are symmetrically disposed based on a central line of the pixel electrode 50 parallel with the gate line 30.

Depending on embodiments, the present exemplary embodiment further includes openings formed on the first domain forming element 310.

When the electric field is applied between the pixel electrode 50 and the common electrode 240, the opening or the first domain forming element 310 functions to control the orientation of liquid crystal molecules in the liquid crystal layer 3000.

When the domain forming conductive pattern 11D and the domain forming semiconductor pattern 130D are consecutively formed through one photolithography process, the domain forming semiconductor pattern 130D may be formed below and on the bottom surface of the domain forming conductive pattern 11D and above and on the top surface of the gate insulating layer 120, such that the domain forming semiconductor pattern 130D is sandwiched between the gate insulating layer 120 and the domain forming conductive pattern 11D.

The domain forming conductive pattern 11D may be formed of the same material as the data line 10, and the domain forming semiconductor pattern 130D may be formed of the same material as the semiconductor pattern 130.

Other constituent elements excluding the first domain forming element 310 are substantially the same as the constituent elements described above with reference to FIGS. 1 through 8. Also, the present exemplary embodiment disclosed in FIG. 11 may be readily adaptable to the exemplary embodiment disclosed in FIG. 9.

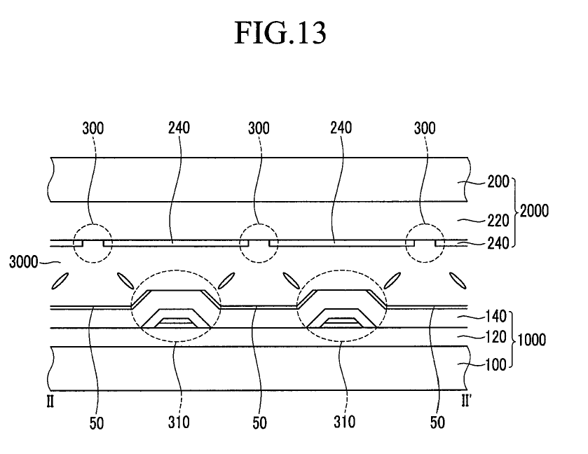

FIG. 13 is a cross-sectional view of an exemplary LCD for forming multiple domains in the exemplary LCD of FIG. 11.

Referring to FIG. 13, in order to effectively form the multiple domains, second domain forming elements 300, and first domain elements 310 or openings formed on the first domain elements 310, are disposed in turn.

Each second domain forming element 300 may correspond to an opening in the common electrode 240. Alternatively, each second domain forming element 300 may be a protrusion (not shown) formed on the common electrode 240, without the opening. The protrusion (not shown) may be formed of a dielectric material on the common electrode 240 by an additional process. In yet another alternative embodiment, the second domain forming elements 300 may include an assortment of openings and/or protrusions.

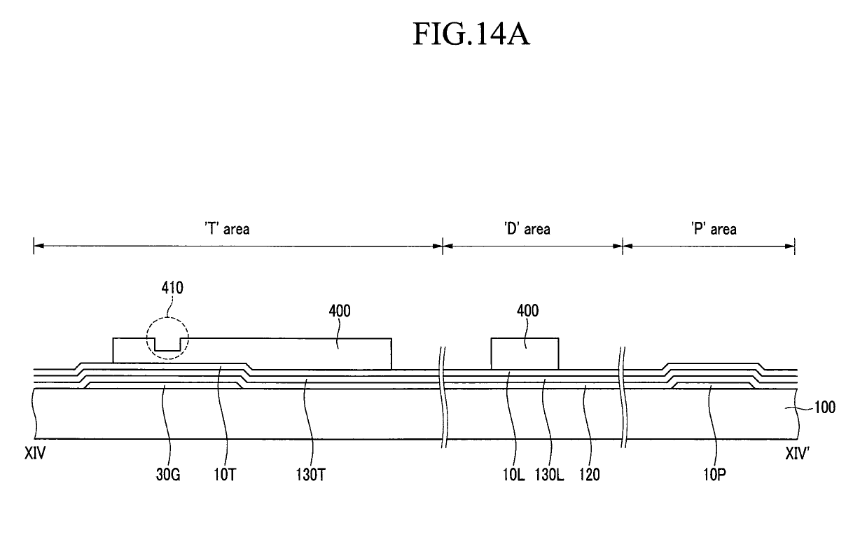

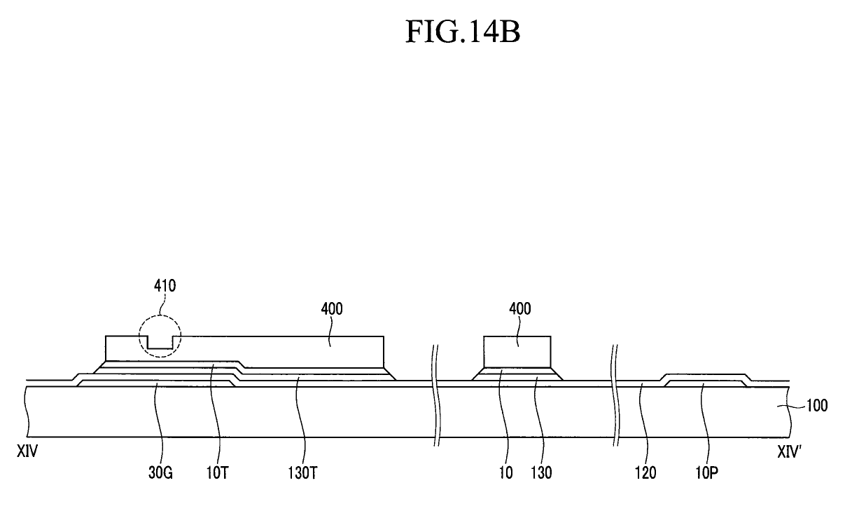

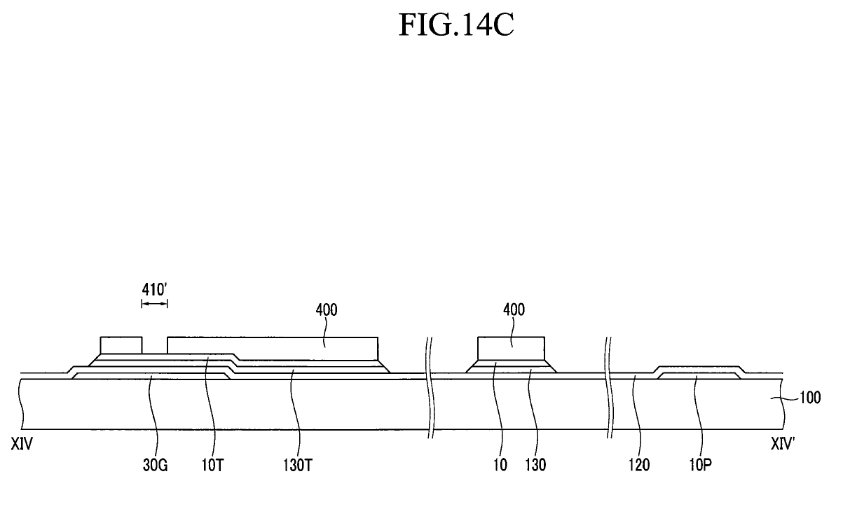

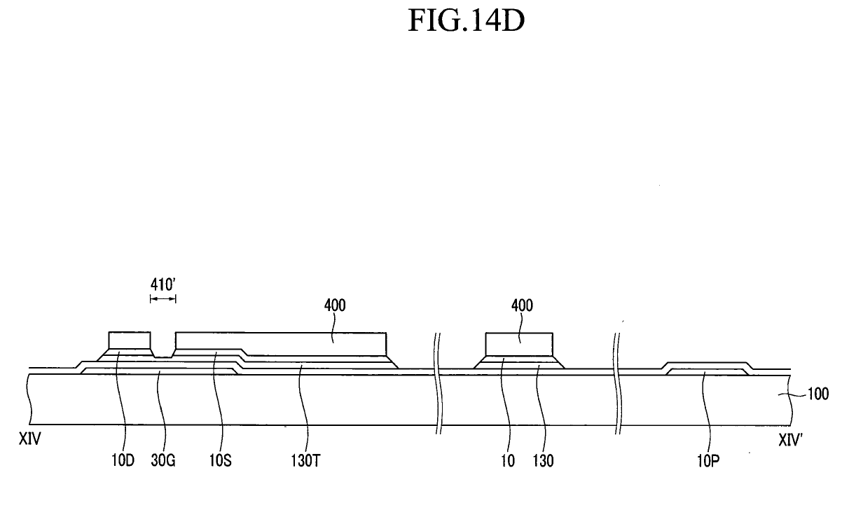

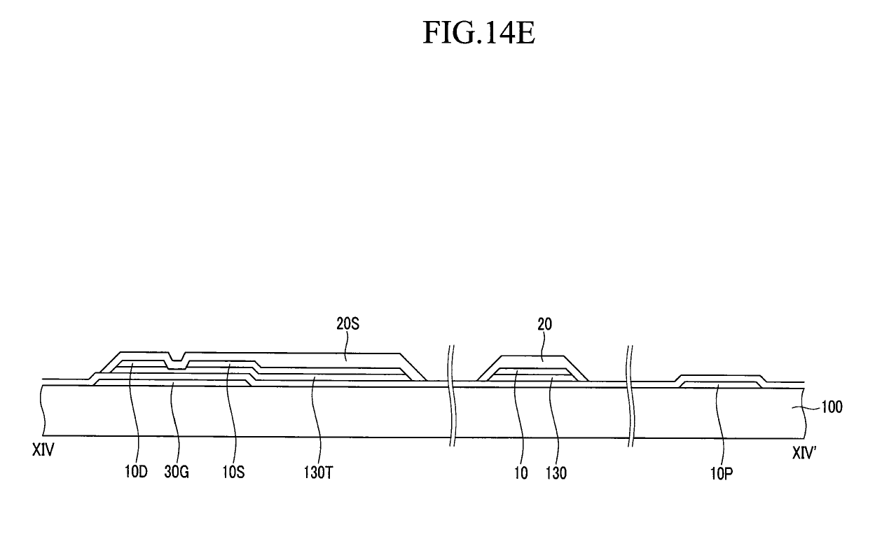

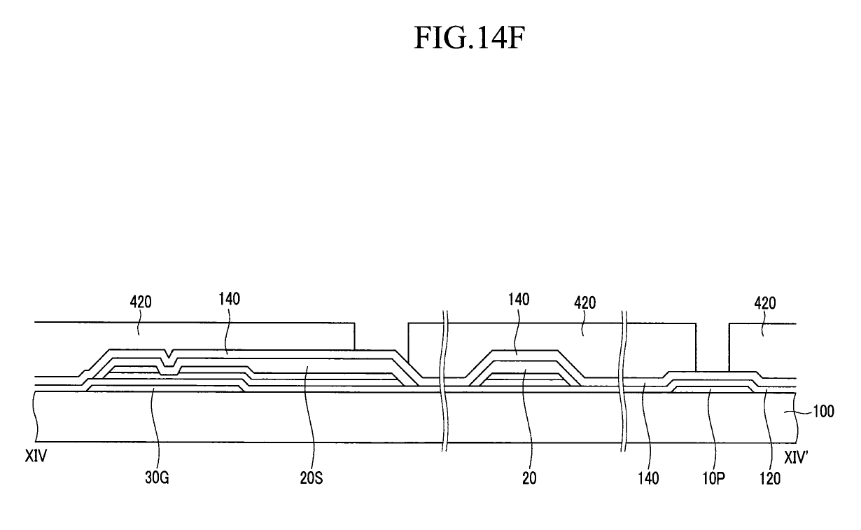

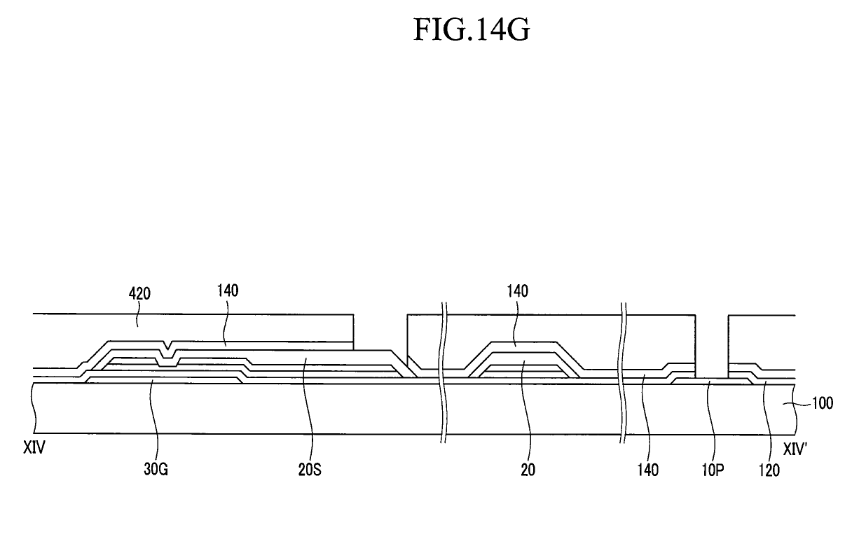

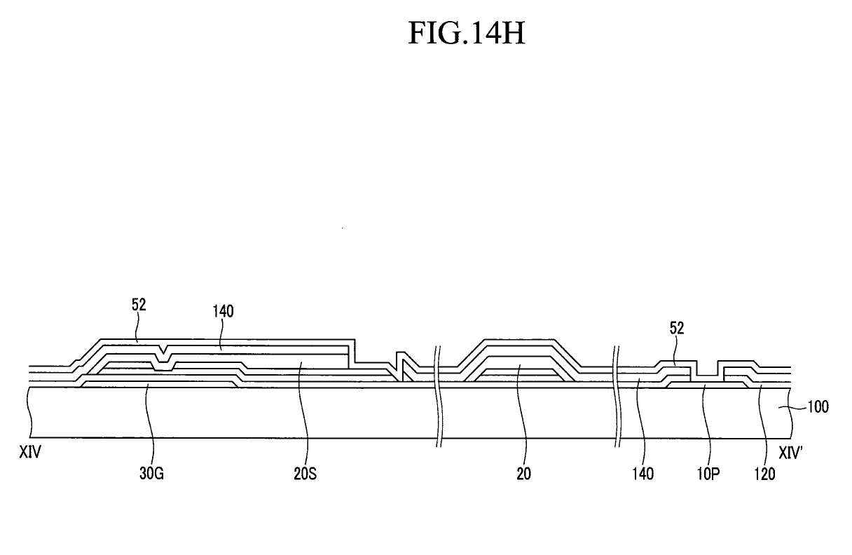

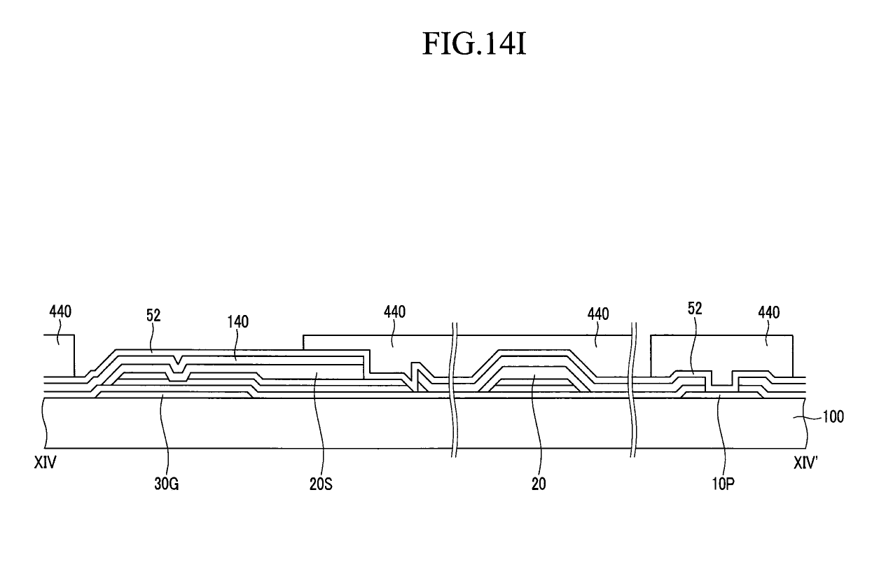

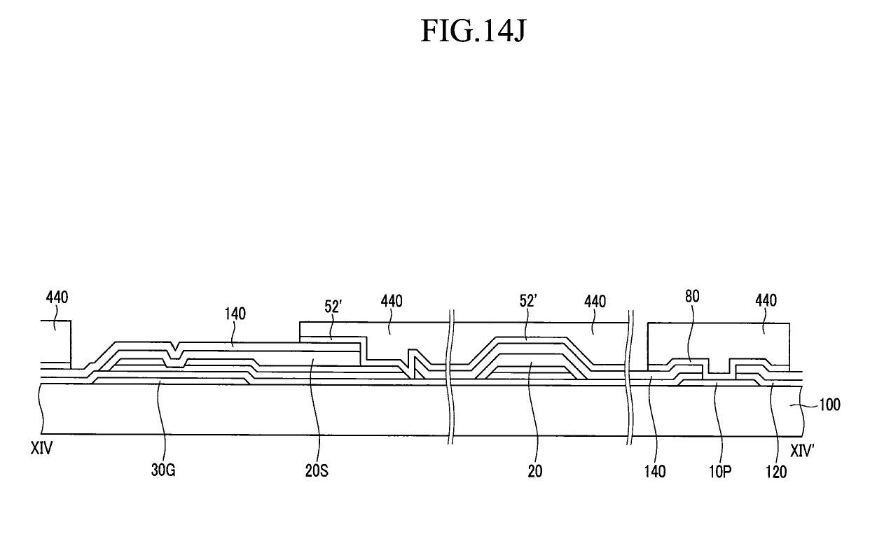

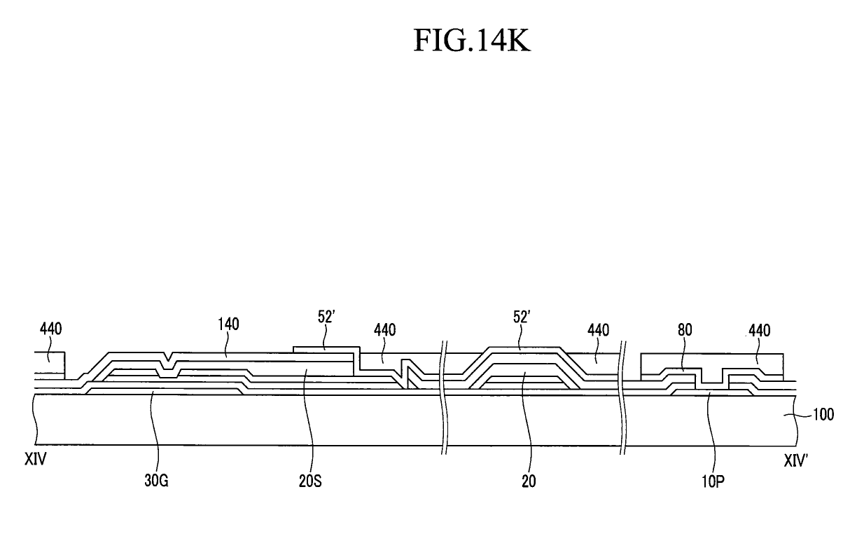

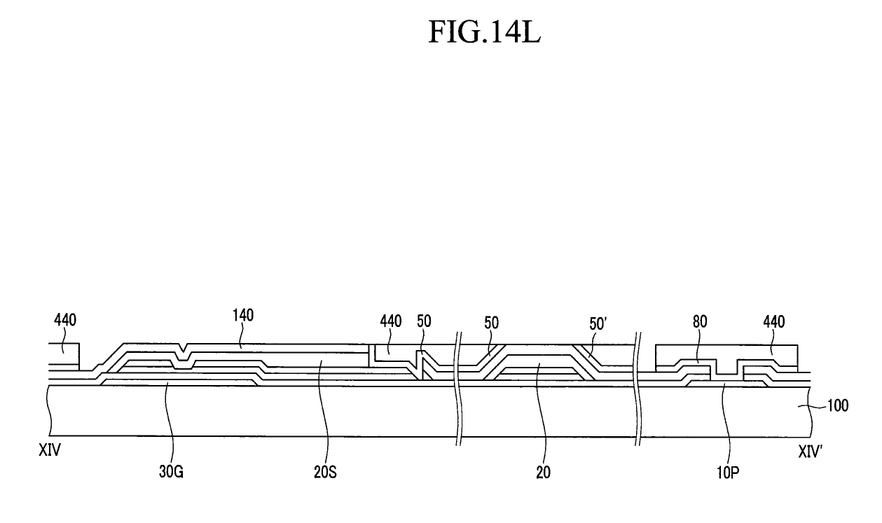

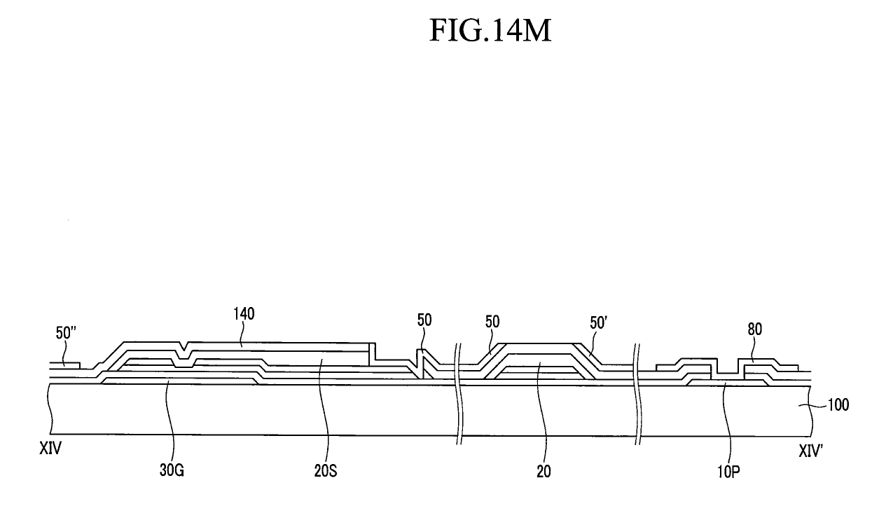

FIGS. 14A to 14M are cross-sectional views of the exemplary lower substrate of the exemplary LCD cut along line XIV-XIV′ of FIG. 1 for describing an exemplary display device manufacturing process.

The cross-sectional views of FIGS. 14A to 14M are associated with a TFT area (hereinafter, “T” area), a data line area (hereinafter, “D” area), and a pad area (hereinafter, “P” area).

Referring to FIG. 14A, layers formed of chromium (Cr), molybdenum (Mo), titanium (Ti), aluminum (Al), or alloys thereof, or combinations thereof, may be formed on the first substrate 100 by a deposition method such as sputtering. Next, the formed layers may be etched through a photolithography process to thereby form the gate electrode 30G connected to the gate line 30 in the “T” area and form the data pad 10P in the “P” area. For example, the gate line 30, the gate electrode 30G, and the data pad 10P may be formed of triple layers of Ti/Al/Ti or Mo/Al/Mo, or dual layers of Al/Ti or Al/Mo from the bottom.

Next, the gate insulating layer 120, a semiconductor layer 130L, and a data metal layer 10L may be consecutively formed on the first substrate 100, the gate electrode 30G, and the data pad 10P by a deposition scheme such as plasma enhancement chemical vapor deposition (“PECVD”). A photoregister pattern 400 may be formed on the data metal layer 10L. The photoregister pattern 400 includes a groove 410. The groove 410 may be formed by a photo process using a mask with a transflective film or a slit pattern.

According to an exemplary embodiment of the present invention, the gate insulating layer 120 may be formed of a silicon nitride layer. The semiconductor layer 130L includes an amorphous silicon layer and an amorphous silicon layer with an added impurity.

Also, the data metal layer 10L may be formed of Cr, Mo, Ti, Al, or alloys thereof, or combinations thereof, and may be the same material or combination of materials used to form the gate line 30.

Referring to FIG. 14B, the semiconductor layer 130L and the data metal layer 10L may be etched using the photoresist pattern 400 to thereby form the semiconductor pattern 130T and the data metal pattern 10T in the “T” area and to form the semiconductor pattern 130 and the data line 10 in the “D” area.

Referring to FIG. 14C, the thickness of the photoregister pattern 400 may be reduced through the etching process, and a portion of the data metal pattern 10T may be exposed in a portion 410′ corresponding to the groove 410.

Referring to FIG. 14D, the exposed data metal pattern 10T may be etched to form the drain electrode 10D and the source electrode 10S in the “T” area. Ohmic contact patterns may be formed on the amorphous silicon pattern by etching an upper portion of the semiconductor pattern 130T using the drain electrode 10D and the source electrode 10S as a mask.

Referring to FIG. 14E, a remaining layer of the photoregister pattern 400 may be reflowed through a thermal process to thereby form organic insulating patterns 20 and 20S in the “D” area and the “T” area. The organic insulating patterns 20 and 20S cover top surfaces and side surfaces of the data line 10, the source electrode 10S, and the drain electrode 10D. Also, the organic insulating patterns 20 and 20S cover side surfaces of the semiconductor patterns 130 and 130T.

The organic insulating pattern 20 is symmetrical based on its central line.

According to an exemplary embodiment of the present invention, the organic insulating patterns 20 and 20S may be formed of a light shielding material.

Referring to FIG. 14F, the passivation layer 140 may be formed on the organic insulating patterns 20 and 20S, and the gate insulating layer 120. Next, in order to form contact holes in the “T” area and the “P” area, photoresist patterns 420 may be formed to expose portions of the passivation layer 140. According to an exemplary embodiment of the present invention, the passivation layer 140 may be formed of a silicon nitride layer, a silicon oxide layer, or a low dielectric material such as SiOC and SiOF.

Referring to FIG. 14G, the passivation layer 140 and the gate insulating layer 120 may be etched by using the photoresist pattern 420 as a mask. The passivation layer 140 and the gate insulating layer 120 may be consecutively or separately etched. Through this etching process, the data pad 10P and the organic insulating pattern 20S may be exposed so as to form the contact holes in the “T” area and the “P” area.

Referring to FIG. 14H, the source electrode 10S may be exposed by etching the exposed organic insulating pattern 20S. Next, the photoresist pattern 420 may be removed. Then, a transparent conductive layer 52, is formed on the passivation layer 140, the source electrode 10S, and the data pad 10P.

Referring to FIG. 141, when again forming a photoresist pattern 440, portions of the transparent conductive layers 52 formed on the passivation layer 140 may be exposed in the “T” area and in the “P” area excluding a portion for forming the auxiliary data pad 80, along the extension direction of the gate line 30.

During this process, the transparent conductive layer 52 formed on the passivation layer 140 in the “D” area along the data line 10 may not be exposed.

Referring to FIG. 14J, the exposed portion of the transparent conductive layer 52 may be etched to thereby form the auxiliary data pad 80 in the “P” area and a first transparent conductive pattern 52′ in the “T” area and the “D” area.

Referring to FIG. 14K, the thickness of the photoresist pattern 440 may be reduced through the etching process to thereby expose the portions of the first transparent conductive patterns 52′. The first transparent conductive patterns 52′ may be exposed in the extension direction of the data line 10. The exposed portions of the first transparent conductive patterns 52′ may correspond to around portions of the passivation layer 140, which are protruded due to the organic insulating patterns 20 and 20S.

Referring to FIG. 14L, the exposed first transparent conductive pattern 52′ may be etched to form the pixel electrodes 50 and 50′ in the “T” area and the “D” area. Boundaries of the pixel electrodes 50 and 50′ may be positioned on inclined surfaces of the passivation layer 140 and may be symmetrically separated with respect to the central line of the organic insulating pattern 20.

Through the above process, substantially the same parasitic capacitances may be formed between the data line 10 and the pixel electrodes 50 and 50′ in the “D” area.

Referring to FIG. 14M, residue of the photoresist pattern 440 may be removed.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A display device comprising:
an insulation substrate;
line wiring formed on the insulation substrate;
an organic insulating pattern covering a top surface and side surfaces of a portion of the line wiring;
a first insulating layer formed on the organic insulating pattern and the insulation substrate; and
transparent conductive patterns formed on the first insulating layer,
wherein boundaries of the transparent conductive patterns are positioned on inclined surfaces of the first insulating layer in a portion of the transparent conductive patterns corresponding to the organic insulating pattern.

2. The display device of claim 1, further comprising
a semiconductor pattern formed between the line wiring and the insulation substrate.

3. The display device of claim 1, wherein the organic insulating pattern is symmetrical based on a central line of the organic insulating pattern, and the boundaries of the transparent conductive patterns are symmetrically disposed based on the central line of the organic insulating pattern.

4. The display device of claim 3, wherein the organic insulating pattern comprises a light shielding material.

5. A display device comprising:
a substrate;
a gate line formed on the substrate;
a gate insulating layer formed on the gate line and the substrate;
a data line formed on the gate insulating layer;
a first organic insulating pattern formed on the data line and the gate insulating layer and covering a top surface and side surfaces of a portion of the data line;
a passivation layer formed on the first organic insulating pattern and the gate insulating layer; and
transparent conductive patterns formed on the passivation layer,
wherein boundaries of the transparent conductive patterns are positioned on inclined surfaces of the passivation layer in a portion of the transparent conductive patterns corresponding to the first organic insulating pattern.

6. The display device of claim 5, further comprising
a semiconductor pattern formed between the data line and the gate insulating layer,
wherein the first organic insulating pattern covers side surfaces of the semiconductor pattern.

7. The display device of claim 5, wherein the first organic insulating pattern is symmetrical based on a central line of the first organic insulating pattern, and the boundaries of the transparent conductive patterns are symmetrically disposed based on the central line of the first organic insulating pattern.

8. The display device of claim 5, wherein the first organic insulating pattern comprises a light shielding material.

9. The display device of claim 5, further comprising:
a storage capacitor line;
a storage capacitor pattern overlapping the storage capacitor line and electrically connected to one of the transparent conductive patterns; and
a second organic insulating pattern formed on the storage capacitor pattern.

10. The display device of claim 9, further comprising
a storage capacitor extension line electrically connected to the storage capacitor line and extended along the data line.

11. The display device of claim 5, further comprising:
a storage capacitor line; and
a storage capacitor pattern overlapping the storage capacitor line and electrically connected to one of the transparent conductive patterns,
wherein one of the transparent conductive patterns comprises an opening formed on the storage capacitor pattern.

12. The display device of claim 5, further comprising
a domain forming semiconductor pattern formed on the gate insulating layer in one of the transparent conductive patterns and obliquely extended with respect to the data line.

13. The display device of claim 12, wherein one of the transparent conductive patterns comprises an opening positioned on the domain forming semiconductor pattern.

14. The display device of claim 5, further comprising
a domain forming conductive pattern formed on the gate insulating layer in one of the transparent conductive patterns and obliquely extended with respect to the data line.

15. The display device of claim 14, wherein one of the transparent conductive patterns comprises an opening positioned on the domain forming conductive pattern.

16. The display device of claim 5, further comprising:
a domain forming semiconductor pattern formed on the gate insulating layer in one of the transparent conductive patterns;
a domain forming conductive pattern formed on the domain forming semiconductor pattern; and
a second organic insulating pattern formed on the domain forming conductive pattern,
wherein the domain forming semiconductor pattern and the domain forming conductive pattern are obliquely extended with respect to the data line.

17. The display device of claim 5, further comprising:
a gate pad electrically connected to the gate line; and
a data pad electrically connected to the data line,
wherein the data pad and the gate pad comprise a same material.

18. The display device of claim 17, further comprising
a bridge conductive pattern electrically connecting the data line and the data pad via the passivation layer and the gate insulating layer,
wherein the bridge conductive pattern comprises a same material as the transparent conductive patterns.

19. The display device of claim 18, further comprising:
an auxiliary gate pad passing through the gate insulating layer via a first contact hole to be electrically connected to the gate pad;
an auxiliary data pad passing through the gate insulating layer via a second contact hole to be electrically connected to the data pad; and
a second semiconductor pattern formed around the first contact hole or the second contact hole.

20. The display device of claim 5, wherein a parasitic capacitance between the data line and one of the transparent conductive patterns is substantially same as a parasitic capacitance between the data line and an adjacent transparent conductive pattern in an extension direction of the gate line.

21. A manufacturing method of a display device, the method comprising:
forming a gate line on a substrate;
forming a gate insulating layer on the gate line and the substrate;
forming a data line on the gate insulating layer;
forming an organic insulating pattern on the data line and the gate insulating layer, wherein the organic insulating pattern covers a top surface and side surfaces of a portion of the data line;
forming a passivation layer on the organic insulating pattern and the gate insulating layer; and
forming transparent conductive patterns on the passivation layer,
wherein boundaries of the transparent conductive patterns are positioned on inclined surfaces of the passivation layer in a portion of the transparent conductive patterns corresponding to the organic insulating pattern.

22. The method of claim 21, wherein
the forming of the data line and the forming of the organic insulating pattern comprise:
forming a data metal layer on the gate insulating layer;
forming an organic insulating layer on the data metal layer;
patterning the organic insulating layer to form an organic insulating mask;
patterning the data metal layer using the organic insulating mask to form the data line; and
reflowing the organic insulating mask to form the organic insulating pattern.

23. The method of claim 22, wherein
the forming of the transparent conductive patterns comprises;
forming a transparent conductive layer on the passivation layer;
forming a photoresist layer on the transparent conductive layer;
patterning the photoresist layer to expose the transparent conductive layer along an extension direction of the gate line;
patterning the exposed transparent conductive layer to form first transparent conductive patterns;
reducing a thickness of the patterned photoresist layer to expose the first transparent conductive patterns along an extension direction of the data line;
patterning the exposed first transparent conductive patterns to form the transparent conductive patterns; and
removing the photoresist layer with the reduced thickness.
